(19) United States
(12) Patent Application Publication
(10) Pub. No.: US 2008/0212267 A1
(43) Pub. Date: Sep. 4, 2008

(54) AUDIOVISUAL CONTROL UNIT

(76) Inventors: Shraga Brosilovski, Tikva (IL); Aviv yosef Brosilovski, Herzelia (IL)

Correspondence Address: APPELFELD ZER FISHER;(Tecom Electronics Ltd), 2 Ben Gurion St., B.S.R Tower 1, Ramat Gan, 52573, omitted

(21) Appl. No.: 12/022,165

(22) Filed: Jan. 30, 2008

Related U.S. Application Data
(60) Provisional application No. 60/900,724, filed on Feb. 12, 2007.

(51) Int. Cl. H05K 7/00

(52) U.S. Cl. 361/679

(57) ABSTRACT

The present invention, in some embodiments thereof, discloses an audiovisual control unit that comprises at least one control panel, at least one controller and at least one audiovisual switch. The controller may enable operating a multiplicity of audio, video and audiovisual electronic devices through the control panel, where the control panel may enable presetting the audiovisual control unit to control said devices according to at least part of the devices' definitions.

The audiovisual control unit and at least some of the electronic devices may be integrated into an audiovisual podium including a housing for compactly positioning the panel and the devices in a single unit.

### FIELD OF THE INVENTION

The present invention relates generally to audio systems and more particularly to audiovisual systems.

### SUMMARY OF THE INVENTION

The present invention is generally directed at the controlling of a multiplicity of electronic audio and video devices and other types of electronic devices, where controlling is carried out through a unified hardware application. The present invention is especially but not exclusively targeted to provide packaging, wiring and operational unified solutions to many types of electronic devices required in lecture halls, classrooms, conference halls, training facilities and the like. Such devices may be, for example, a microphone, a projector, a camera, a computer, a laptop, a video cassette recorder (VCR), a digital video (DV) and the like.

### BRIEF DESCRIPTIONS OF THE DRAWINGS

The subject matter regarded as the invention will become more clearly understood in light of the ensuing description of embodiments herein, given by way of example and for purposes of illustrative discussion of the present invention only, with reference to the accompanying drawings, wherein

FIG. 1 is a schematic illustration of an audiovisual control unit, according to embodiments of the present invention.

FIG. 2 is a schematic illustration of audiovisual control unit connections to a multiplicity of electronic devices, according to embodiments of the present invention.

FIG. 3 is a schematic illustration of an audiovisual podium, according to embodiments of the present invention.

FIG. 4 is a schematic illustration of an audiovisual podium's power deliverance, according to embodiments of the present invention.

FIG. 5 is a schematic illustration of an electronic pen addition to the audiovisual podium, according to embodiments of the present invention.

FIG. 6 is a schematic illustration of a data cable retrieving mechanism, according to embodiments of the present invention.

FIG. 7 is a schematic illustration of ventilation openings, according to embodiments of the present invention.

The drawings together with the description make apparent to those skilled in the art how the invention may be embodied in practice.

An embodiment is an example or implementation of the inventions. The various appearances of “one embodiment,” “an embodiment” or “some embodiments” do not necessarily all refer to the same embodiments. Although various features of the invention may be described in the context of a single embodiment, the features may also be provided separately or in any suitable combination. Conversely, although the invention may be described herein in the context of separate embodiments for clarity, the invention may also be implemented in a single embodiment

### DETAILED DESCRIPTIONS OF SOME EMBODIMENTS OF THE INVENTION

The present invention is a system that comprises an audiovisual control unit (ACU) 100 that comprises a controller 10 and a control panel 20. ACU 100 may be connected to a multiplicity of electronic devices through an audiovisual switch 300, where ACU 100 may be able to control over at least part of the devices' functions through a unified hardware application, which is ACU 100, according to some embodiments of the present invention. A user of the system may be able to control the devices' functions through control panel 20. Such functions may be, for example, volume level and sound features (such as bass level), on and off options for all or part of the connected devices, play, stop and pause options for the VCR, etc.

While the description below contains many specifications, these should not be construed as limitations on the scope of the invention, but rather as exemplifications of the preferred embodiments. Those skilled in the art will envision other possible variations that are within its scope. Accordingly, the scope of the invention should be determined not by the embodiment illustrated, but by the appended claims and their legal equivalents.

Reference in the specification to “one embodiment”, “an embodiment”, “some embodiments” or “other embodiments” means that a particular feature, structure, or characteristic described in connection with the embodiments is included in at least one embodiments, but not necessarily all embodiments, of the inventions. It is understood that the phraseology and terminology employed herein is not to be construed as limiting and are for descriptive purpose only.

The principles and uses of the teachings of the present invention may be better understood with reference to the accompanying description, figures and examples. It is to be understood that the details set forth herein do not construe a limitation to an application of the invention. Furthermore, it is to be understood that the invention can be carried out or practiced in various ways and that the invention can be implemented in embodiments other than the ones outlined in the description below.

It is to be understood that the terms “including”, “comprising”, “consisting” and grammatical variants thereof do not preclude the addition of one or more components, features, steps, or integers or groups thereof and that the terms are to be construed as specifying components, features, steps or integers. The phrase “consisting essentially of”, and grammatical variants thereof, when used herein is not to be construed as excluding additional components, steps, features, integers or groups thereof but rather that the additional features, integers, steps, components or groups thereof do not materially alter the basic and novel characteristics of the claimed composition, device or method.

If the specification or claims refer to “an additional” element, that does not preclude there being more than one of the additional element. It is to be understood that where the claims or specification refer to “a” or “an” element, such reference is not be construed that there is only one of that element. It is to be understood that where the specification states that a component, feature, structure, or characteristic “may”, “might”, “can” or “could” be included, that particular component, feature, structure, or characteristic is not required to be included.

Where applicable, although state diagrams, flow diagrams or both may be used to describe embodiments, the invention is not limited to those diagrams or to the corresponding descriptions. For example, flow need not move through each illustrated box or state, or in exactly the same order as illustrated and described.

Methods of the present invention may be implemented by performing or completing manually, automatically, or a combination thereof, selected steps or tasks. The term “method” refers to manners, means, techniques and procedures for accomplishing a given task including, but not limited to, those manners, means, techniques and procedures either known to, or readily developed from known manners, means, techniques and procedures by practitioners of the art to which the invention belongs. The descriptions, examples, methods and materials presented in the claims and the specification are not to be construed as limiting but rather as illustrative only.

Meanings of technical and scientific terms used herein are to be commonly understood as by one of ordinary skill in the art to which the invention belongs, unless otherwise defined. The present invention can be implemented in the testing or practice with methods and materials equivalent or similar to those described herein.

Any publications, including patents, patent applications and articles, referenced or mentioned in this specification are herein incorporated in their entirety into the specification, to the same extent as if each individual publication was specifically and individually indicated to be incorporated herein. In addition, citation or identification of any reference in the description of some embodiments of the invention shall not be construed as an admission that such reference is available as prior art to the present invention.

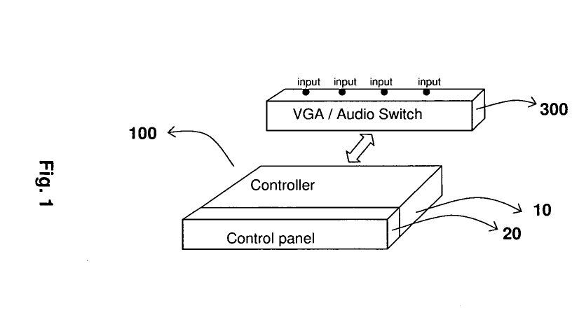

FIG. 1 schematically illustrates Audiovisual Control Unit (ACU) 100, according to embodiments of the present invention. Control panel 20 is connected to controller 10, where controller 10 is connected to audiovisual switch 300. Audiovisual switch 300 includes inputs that provide connection to the electronic devices' outputs.

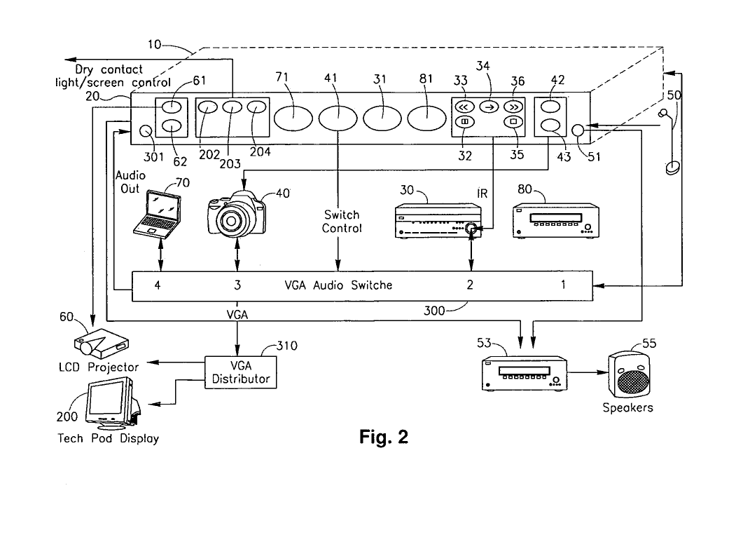

FIG. 2 schematically illustrates ACU 100 connections to a multiplicity of electronic devices, according to embodiments of the present invention. According to an example illustrated in FIG. 2, ACU 100 enables connection and control over a microphone 50, a VCR 30, a camera 40, a laptop 70, a computer 80, a projector 60 and a screen 200. At least part of the electronic devices are connected to the input portals of audiovisual switch 300. Audiovisual switch 300 may be a video graphic array (VGA) and audio switch, to enable both visual signals and audio signals to be transmitted. At least part of the electronic devices may be connected to audiovisual switch 300 through a VGA distributor 310 that enables distribution of VGA signals to more than one visual displayers such as projector 60 and screen 200, according to this embodiment of the invention.

According to embodiments of the present invention, camera 40 may be any kind of camera that enables transmission of visual data to projector 60, for example, a video camera, a stills camera, a document camera (visualizer) and the like.

According to embodiments of the present invention, control panel 20 may provide a user interface that controls over different features and functions of the electronic devices. According to embodiments of the present invention illustrated in FIG. 2, control panel 20 enables:
tuning of microphone's 50 volume through, for example, a microphone volume tuner 51;
turning projector 60 on and off through a projector “on” button 61 and a projector “off” button 62;
switching to each devices mode through switches such as a laptop switch 71, a camera switch 41, a VCR switch 31 and a computer switch 81;
lights switching through, for example, front light switch 202, back light switch 203 and a dimmer 204; each switch may control switching or dimming of different light sources, for example, at least part of the room's lights, the lecturing stage lights etc.
controlling camera 40 by, for example, zooming with a zoom in 42 and a zoom out 43 buttons;
controlling the volume of audio output of the electronic devices through, for example, a volume tuner 301;
and controlling over VCR 30 functions with, for example, a play button 34, a pause button 32, a stop button 35, a fast-forward button 36 and a rewind button 33.
   Audiovisual switch 300 enables switching from one device to another according to each device's wiring, where ACU 100 may require presetting according to the definitions of each connected electronic device.

According to embodiments of the present invention, an amplifier 53 may provide volume amplification and sound tuning to the whole system through the volume tuners 51 and 301. For example, microphone 50 may be connected to a potentiometer that enables the tuning of microphone tuner 51, where microphone 50 is connected to the input of the potentiometer and amplifier 53 may be connected to the output of the potentiometer. Amplifier 53 may be connected to at least one speaker. Volume tuner may be connected to yet another potentiometer, for example, where audiovisual switch 300 may be connected to the input of the potentiometer and amplifier 53 may be connected to the output of the potentiometer.

According to embodiments of the present invention, potentiometers may be installed in control panel 20 as well as in controller 10 or through any other external connection to the ACU 100.

According to other embodiments of the present invention, the system may be connected to more than one amplifier.

According to embodiments of the present invention, ACU 100 may be preset to enable various kinds of inputting of the electronic devices, corresponding to the electronic devices' specifications predefined by the system. For example, projector 60 may be an LCD projector 60 that usually requires an infra-red (IR) connection, meaning that the input of controller 10 or control panel 20 may be set to be IR inputs to allow the IR cable of projector 60 to be inserted. As another example, computer 80 may require a universal serial bus (USB) connection, so that controller 10 or control panel 20 may be pre-designed to allow USB connections.

According to embodiments of the present invention, ACU 100 may be connected to a standard AC power source.

According to some embodiments of the ACU 100, ACU 100 may require resetting according to at least some of the connected electronic devices. The resetting may be carried out by a user using, for example, control panel 20 options. For example, to reset ACU 100 according to VCR 30 definitions, the user may be required to connect VCR 30 to ACU 100 through audiovisual switch 300; press the play button of VCR 30 and simultaneously press play button 34 in control panel 20. In the same way, simultaneously pressing of the same function buttons of VCR 30 and ACU 100 may automatically set ACU 100 according to a specific VCR 30 functions. ACU 100 may automatically store and “learn” at least part of the operation commands and settings of at least part of the electronic devices that are connected to the system.

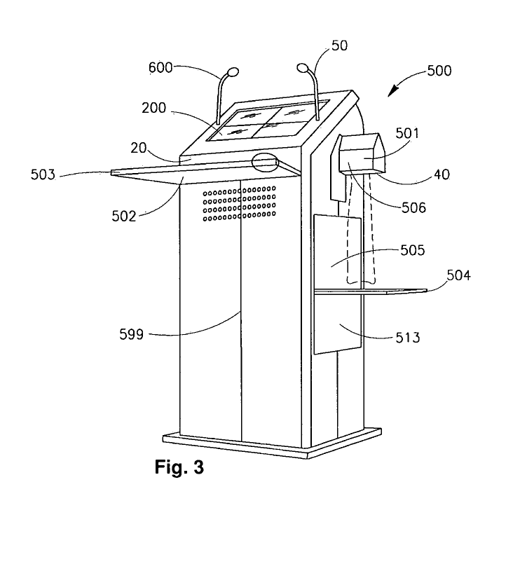

FIG. 3 schematically illustrates an audiovisual podium (AP) 500, according to embodiments of the present invention. AP 500 includes ACU 100 and at least some of the electronic devices, along with a packaging 599 that may be structured to house at least one electronic device along with at least part of the attached and held electronic devices' wiring and power source connections.

According to embodiments of the present invention as illustrated in FIG. 3, AP 500 may include:
a packaging 599 which is a three dimensional structure enveloping a cavity inside-space. Packaging 599 may house at least part of the electronic devices, and may esthetically conceal some of the wires and the electronic devices;
a tray 503 that may be seated at the front side of AP 500;
a housing 501 that may hold camera 40 and a lamp 506;
a door 504, where door 504 opens and closes an opening 505 of AP 500 side and where door 504 may be affixed on a hinge 513 that facilitates the opening and closing movement;
microphone 50;
a screen 200;
a desk lamp 600;
a drawer 502 that may be seated underneath tray 503 to enable esthetical storage of AP 500 gadgets such as a computer mouse, a keyboard and the like.
   According to embodiments of the present invention, control panel 20, screen 200 and tray 503 may be seated at the upper front side of AP 500, as illustrated in FIG. 3, to provide a user with a comfortable access to those components at a user's standing level, for example. Screen 200 may be seated at AP 500 upper front side with an angle that may tilt screen 200 ergonomically facilitating a user's viewing of screen 200. Tray 503 may be used to hold a keyboard and a mouse for using a computer installed into AP 500. Housing 501 may hold camera 40 and lamp 506 in a position that directs lamp's 506, and camera 40 to photograph and light the area of door 504 when it is in an open position, as illustrated in FIG. 3, according to embodiments of the present invention. Projector 60 may be connected to AP 500 through VGA distributor 310, where samples and papers that are placed on door 504 may be lighted by lamp 506 and photographed by camera 40, where the photographed images may be transmitted to be projected by projector 60.

According to embodiments of the present invention, controller 10 and audiovisual switch 300 may be seated at the inside cavity of opening 505. Other electronic devices may also be seated in the cavity of opening 505 such as, for example, VCR 30, computer 80, a DV and amplifier 503. Opening 505 may facilitate in accessing those devices for the purpose of tuning, wiring, switching and the like. For example, to preset VCR 30 with control panel 20 function buttons, a user may be required to press VCR 30 buttons—accessing VCR 30 function buttons through opening 505.

According to embodiments of the present invention, AP 500 may further include additional trays, lamps and microphones.

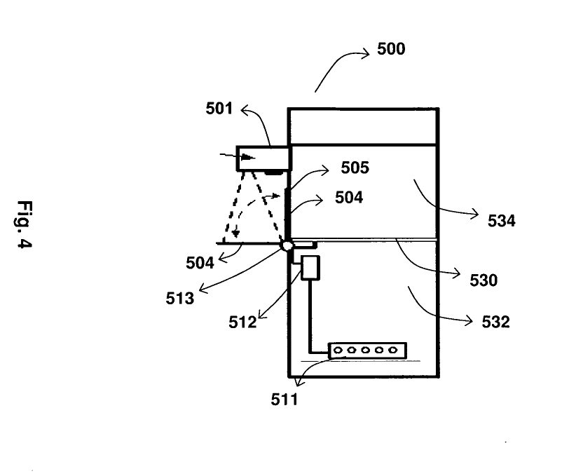

FIG. 4 schematically illustrates AP 500 power deliverance, according to embodiments of the present invention. AP 500 may be plugged to a standard power distributor 511, such as alternative currant (AC) distributor 511 that may distribute power supply to at least part of the electronic devices that are attached to AP 500 including ACU 100.

According to embodiments of the present invention, switching the power supply of at least part of the electronic devices that are integrated in AP 500 may be carried out by opening and closing of door 504. For example closing of door 504 may turn the power off and opening door 504 may turn the power on. According to embodiments of the present invention, to facilitate such a switching mechanism, a micro-switch 512 may connect distributor 511 with a hinge 513, so that when door 504 is open—an electric circuit may be closed to enable electric currant flow, providing an “on” position. Accordingly, when door 504 is closed—the electric circuit may be opened and electric flow cut, providing an “off” position.

According to embodiments of the present invention, AP 500 inner cavity may be divided into two sections by a shelf 530, creating two cabins: an upper cabin 534 and a lower cabin 532, as illustrated in FIG. 4. Shelf 530 may facilitate in holding of electronic devices and controller 10.

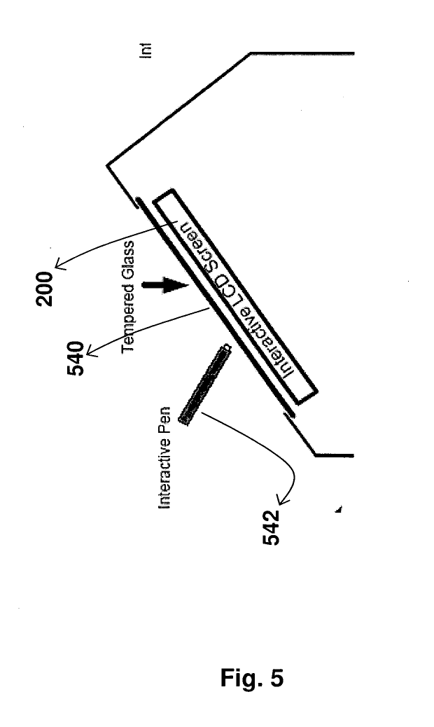

According to embodiments of the present invention, screen 200 may be seated within AP 500, as illustrated in FIG. 5. screen 200 may be plated with a protecting transparent material or seated beneath a transparent material that may protect screen 200 from being touched, for example a tempered glass 540 covering, as illustrated in FIG. 5, according to embodiments of the present invention.

According to embodiments of the present invention, screen 200 may be an interactive touch screen 200 that allows the use of an interactive electronic pen 542, as illustrated in FIG. 5. For example, an interactive LCD screen 200 that allows a refined and high-resolution use of electronic pen 542, while the touch screen 200 allows software applications that enable commencing of functions through screen touch-buttons. The user may write down on the screen 200 or on tempered glass 540, using pen 542, while the writing may be projected through projector 60 onto a big screen through software applications that enable reading of the drawings created by the user using pen 542.

According to embodiments of the present invention, computer 80 or laptop 70 may be installed into ACU 100 and seated at AP 500, where the computer that is integrated into AP 500 comprises software applications that facilitate the use of electronic pen 542 and an interactive screen 200.

According to embodiments of the present invention, ACU 100 may further include network communication and plugging equipment and applications, such as a modem, network interface card (NIC), network cabling, etc. According to additional or alternative embodiments of the present invention, AP 500 may include network communication and plugging equipment and applications.

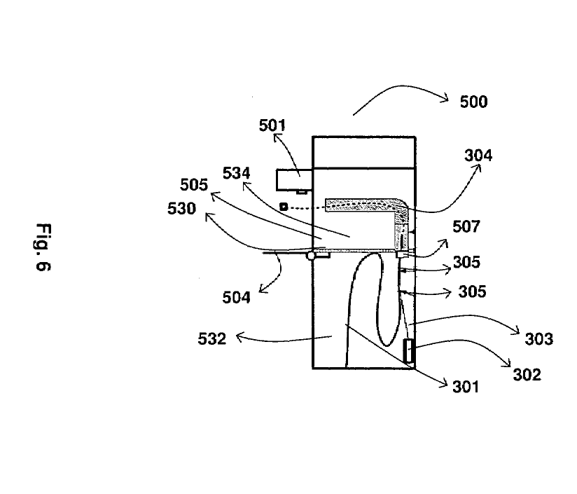

According to embodiments of the present invention, and as illustrated in FIG. 6, AP 500 may further comprise a data cable and a mechanism for retrieving of at least one data cable 301 that may be installed within AP 500 inner cavity. Data cable 301 may be any cable that facilitates operation of an electronic device, where that device is seated externally to AP 500. For example, an external laptop 70 that requires a VGA/audio cable for connecting to the AP 500 through ACU 100. Data cable 301 may be VGA and audio cable, USB cable, IR cable, network cable and the like, and may be connected at one end to the external electronic device and to audiovisual switch 300 or to other switching or signal distributing devices.

According to the embodiments illustrated in FIG. 6, a retriever 302 may be installed at bottom cabin 532 of AP 500. Retriever 302 has a retrieving spring 303 that is coiled inside retriever 302. Spring 303 may have at least one cable-holder 305 that holds data cable 301. Data cable 301 may be inserted from bottom cabin 532 to upper cabin 534 through a shelf opening 507, which may be an opening that is perforated in shelf 530. In upper cabin 534—data cable 301 is threaded through a guiding tube 304, where guiding tube 304 may be designed in an L shape, as illustrated in FIG. 6, to facilitate the smooth threading of data cable 301 when it is being pulled or retrieved. Spring 303 is held in a tense position since cable-holders 305 facilitate in exerting tension by being affixed to lower cabin 532 inner walls. A user may pull data cable 301 in order to connect it to an external device. When pulling, spring 303 exerts a contrasting force to that of the pulling. When releasing data cable 301, the tension of spring 303 may be loosed and data cable 301 may automatically retrieve back through guiding tube 304.

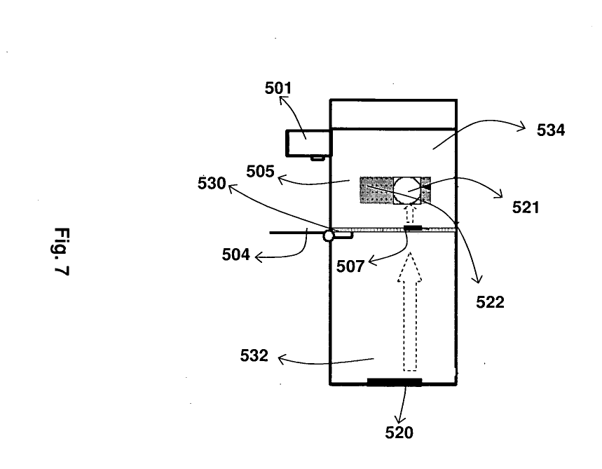

According to embodiments of the present invention, as illustrated in FIG. 7, AP 500 may include a floor opening 520, a shelf opening 507, at least one fan 521 and at least one perforated wall-section 522, which may be a portion of one of AP's 500 walls that is perforated. Fan 521 and perforated wall-section 522 may facilitate the flow of air within the upper cabin 534. Shelf opening 507 and floor opening 520 may facilitate in the flow of air from the bottom of AP 500 to the lower cabin 532. Fan 521 may draw air that has entered lower cabin 532 through floor opening 520 and shelf opening 507 and direct this air to flow outside of AP 500 through perforated wall-section 522.

According to some embodiments of the present invention, ACU 100 may farther include computer 80 and screen 200 as an integrated control unit, to allow setting ACU 100 according to the electronic devices' definitions, through a software application and a user interface. The software and user interface may enable the said setting as well as at least part of the functions of control panel 20. For example, a user interface that allows tuning the volume and sound through a touch screen functions, as well as setting VCR 30 functions while pressing touch screen buttons over screen 200, etc.

According to some embodiments of the present invention, AP 500 may include a height adjustment unit that may enable height adjustment of AP 500. The height adjustment unit may be based on a hydraulic mechanism. Packaging 599 may be integrated by packaging pieces such as metallic sheets, wood boards and the like, that may allow telescopic folding, accordion folding, or any other mechanism that enables the shortening of AP 500 packaging 599. The height adjustment may be carried out automatically through an electronic control or manually.

While the invention has been described with respect to a limited number of embodiments, these should not be construed as limitations on the scope of the invention, but rather as exemplifications of some of the preferred embodiments. Those skilled in the art will envision other possible variations, modifications, and applications that are also within the scope of the invention. Accordingly, the scope of the invention should not be limited by what has thus far been described, but by the appended claims and their legal equivalents.

What is claimed is:

1. An audiovisual control unit (ACU) that comprises at least one control panel, at least one controller and at least one audiovisual switch, where the controller enables operating a multiplicity of audio, video and audiovisual electronic devices through the control panel, wherein said control panel enables presetting the ACU to control said devices according to at least part of the devices' definitions.

2. The ACU of claim 1, wherein the said ACU and at least one of the said electronic devices are integrated into an audiovisual podium (AP).
